(19) United States
(12) Patent Application Publication
(10) Pub. No.: US 2026/0337817 A1
(43) Pub. Date: Oct. 29, 2026

(54) METHOD FOR PRODUCING A MONOCRYSTALLINE DIAMOND PLATE, MONOCRYSTALLINE DIAMOND PLATE AND MONOCRYSTALLINE DIAMOND WAFER OF LARGE SIZE

(71) Applicant: HIQUTE DIAMOND, Boulogne-Billancourt (FR)

(72) Inventors: Alix Gicquel, Trouville-Sur-Mer (FR); Olivier Duigou, Massy (FR); Alibi Baitukha, Paris (FR)

(21) Appl. No.: 19/111,002

(22) PCT Filed: Sep. 13, 2023
(86) PCT No.: PCT/EP2023/075103

§ 371 Date: Mar. 12, 2025

(30) Foreign Application Priority Data
Sep. 13, 2022 (FR) FR2209174

(51) Int. Cl. C30B 25/20; C30B 29/04; C30B 31/06; C30B 33/02; C30B 33/04

(52) U.S. Cl. CPC C30B 25/20; C30B 29/04; C30B 31/06; C30B 33/02; C30B 33/04

(57) ABSTRACT

The invention relates to a method for producing (100) a monocrystalline diamond plate from a plurality of monocrystalline diamond seeds (10, 11, 12, 13) which include a growth surface, said growth surface comprising a terraced structure, said terraced structure having several crystallographic orientation faces (OC1, OC2), said crystallographic orientation faces (OC1, OC2) comprising families of planes {100} or families of planes {100} and {113}, the method comprising the following steps:
supply (110) of monocrystalline diamond seeds (10, 11, 12, 13),
positioning (130) of the monocrystalline diamond seeds (10, 11, 12, 13) so as to form a mosaic,
lateral epitaxial growth (140) of the terraced structure according to the crystallographic orientation (OC2).

### TECHNICAL FIELD

The invention relates to the field of the manufacture of diamonds, more specifically of large-size monocrystalline diamonds.

### PRIOR ART

Hereinafter the known prior art from which the invention has been developed is described.

Diamond is a material that has physical properties that are particularly appreciated in many areas. In particular, diamond has unparalleled properties as a semiconductor material, such as high thermal conductivity, high electron/hole mobility, high dielectric breakdown electric field intensity, low dielectric loss, and a wide bandgap, radiation resistance, high chemical stability and excellent optical properties.

Monocrystalline diamond remains one of the most promising materials for the preparation of high-power, high-frequency, high-temperature, voltage-resistant, and quantum optoelectronic devices.

In particular, in order to put diamond into practice as a semiconductor material, a wafer made of monocrystalline diamond having a large surface and high homogeneity may be required for some applications.

To allow the formation of monocrystalline diamond wafers with increasingly large sizes, several growth methods have emerged, among them, the methods for manufacturing monocrystalline diamond plates by epitaxial step flow growth have allowed to get good quality monocrystalline diamond wafers.

Generally, to produce a large-size monocrystalline diamond plate, several monocrystalline diamond seeds are disposed side by side so as to form a mosaic and undergo epitaxial growth by plasma-enhanced chemical vapor deposition. During epitaxial growth, joints are formed between the seeds. The grown monocrystalline diamond surface must then be polished to form a smooth surface before it can be used as a monocrystalline diamond plate for the growth of a monocrystalline epitaxial layer.

The main technical difficulty is related to the formation of junctions between the seeds, with little or no crystalline defects such as dislocations, twins, a modification of the direction of propagation of the wave front. Indeed, the greater the size of the monocrystalline diamond plate, the greater the number of seeds necessary to form it and the greater the risk of seeing crystalline defects appear in the junctions.

The presence of these crystalline defects is critical since in addition to the fact that this has an impact on the quality of the monocrystalline diamond produced, the crystalline defects also have an impact during the polishing and cutting phases of the epitaxial layer formed on the growth surface. Monocrystalline junctions are thus more fragile and can break more easily. Furthermore, stresses, often responsible for these crystalline defects, can also generate invoices during the growth of the epitaxial layer.

Solutions aimed at partly resolving the problems mentioned above have emerged, in particular document n° WO2019139147 relates to a method for producing a monocrystalline substrate for a semiconductor formed on a large-size monocrystalline diamond plate. The proposed solution allows to limit the risk of destruction of the monocrystalline diamond plate after cutting. For this purpose, provision is made to use four monocrystalline diamond seeds, which have a crystallographic orientation of the family {100}, of 10 mm by 10 mm linked so as to form a mosaic. A plate, formed by monocrystalline diamond seeds, is recovered by a removal step using a “lift-off” method that is to say by removal of a sacrificial material. As a result, the process for cutting and polishing the developed diamond plate is no longer necessary, thus limiting the risk of deterioration of the plates during the polishing and cutting phases.

Another solution described in document n° CN114150376 proposes a method for splicing and growing a large-size monocrystalline diamond, having a high crystalline quality at the splice junctions formed during the monocrystalline diamond seed growth process. For this purpose, from a monocrystalline diamond seed of crystallographic orientation of the family {100}, a monocrystalline diamond epitaxial layer is formed on the surface of the seed by chemical vapor deposition. The epitaxial layer is recovered by laser cutting. This step is repeated so as to obtain a plurality of epitaxial layers with strictly identical crystal orientations. The epitaxial layers are polished to reduce their height difference. The step flow growth direction on the surface of the epitaxial layers is then determined and the epitaxial layers are arranged parallel to the stepped flow growth direction then used as seeds for the growth of a monocrystalline diamond epitaxial layer by chemical vapor deposition. A large-size monocrystalline diamond epitaxial wafer is thus obtained.

Although obtaining thick diamond layers by plasma-enhanced chemical vapor deposition from seeds of crystallographic orientation of the family {100} also allows to obtain monocrystalline diamond mosaics with good quality junctions, these methods do not allow to produce monocrystalline diamond plates of sufficient size for the formation of substrates for electronic applications. Furthermore, the solutions proposed in the prior the art involve the application of fairly restricted growth conditions imposing a relatively low growth rate and preventing the incorporation of impurities by doping which would modify the properties of the monocrystalline diamond plate.

Thus, there is a need for the provision of monocrystalline diamond plates which have increased growth surface and improved quality.

The object of the invention is to overcome the disadvantages of the prior art. In particular, the object of the invention is to propose a method for producing a large-size monocrystalline diamond plate, said method allowing to ensure the formation of high-quality junctions, that is to say with little or even no crystalline defects, between monocrystalline diamond seeds.

### SUMMARY OF THE INVENTION

The invention aims at overcoming these disadvantages. The following presents a simplified summary of selected aspects, embodiments and examples of the present invention for the purpose of providing a basic understanding of the invention. However, this summary is not an exhaustive overview of all aspects, embodiments and examples of the invention. Its only purpose is to present selected aspects, embodiments and examples of the invention in a concise form as an introduction to the more detailed description of the aspects, embodiments and examples of the invention which follow the summary.

The invention relates in particular to a method for producing a monocrystalline diamond plate from a plurality of monocrystalline diamond seeds which include a growth surface, said growth surface comprising a terraced structure, said terraced structure having several crystallographic orientation faces, said crystallographic orientation faces including families of planes {100} or families of planes {100} and {113}, the method comprising the following steps:
supply of monocrystalline diamond seeds, each of the seeds being associated with structural characteristics, said structural characteristics comprising at least:
   a first value describing an angle giving a direction of propagation of a wave front,
   a disorientation angle of the terraced structure greater than or equal to 0° and less than or equal to 10°,
positioning of the monocrystalline diamond seeds so as to form a mosaic, so that two adjacent monocrystalline diamond seeds have first values describing the angles giving the directions of propagation of the wave fronts whose difference is less than or equal to 5°, preferably less than or equal to 1°; and
lateral epitaxial growth of the terraced structure, by enhanced chemical vapor deposition, preferably by plasma or by hot filament, of a monocrystalline layer.

Thus, this allows to use a large number of monocrystalline diamond seeds and therefore, compared to the methods of the prior art, to increase the available growth surface of the monocrystalline diamond plate from which monocrystalline diamond wafers can be generated. In particular, the lateral epitaxial growth of the terraced structure is carried out according to the crystallographic orientation comprising families of planes {100} and {113}, preferably it is the crystallographic orientation forming the heights of the steps of the terraced structure. This lateral epitaxial growth allows the formation of junctions between the seeds.

Such a method also allows faster growth than that permitted by the methods of the prior art, while maintaining optimum crystalline quality. The method according to the invention also allows to modify the physical characteristics of the monocrystalline diamond or of the surface of the monocrystalline diamond by the use of doping gas followed by irradiation, for example with a flow of electrons and in particular the incorporation of centers NV and NV⁻ or XV and XV⁻, X being an element such as nitrogen N or silicon Si for example.

The invention further aims at providing a large-size monocrystalline diamond plate. Such a monocrystalline diamond plate has a larger growth surface than that permitted by the methods of the prior art, and an optimal crystalline quality with few or even no crystalline defects.

As will be shown, the method according to the invention can be effective even when, during the step of positioning the seeds, two adjacent monocrystalline diamond seeds have first values describing the angles giving the directions of propagation of the wave fronts whose difference is greater than 0°.

According to other optional features of the method for producing a monocrystalline diamond plate, the latter may optionally include one or more of the following features, alone or in combination:
wherein the lateral epitaxial growth step is followed by a second vertical epitaxial growth of the terraced structure according to the crystallographic orientation of the family of planes {100} so as to form a monocrystalline diamond epitaxial layer. In particular, it is the lateral epitaxial growth step according to the crystallographic orientation of the monocrystalline diamond seeds comprising families of planes {100} or of monocrystalline diamond seeds comprising families of planes {100} and {113} which is followed by the second vertical epitaxial growth.
wherein the first value describing an angle giving a direction of propagation of a wave front of a monocrystalline diamond seed corresponds to an angle formed between the direction of propagation of the wave front and a lateral face of the monocrystalline diamond seed.
wherein the first value describing an angle giving a direction of propagation of a wave front of a monocrystalline diamond seed corresponds to a vector characteristic of the direction of propagation of a wave front relative to a lateral face of the monocrystalline diamond seed.
a step of calculating, from the first values describing a direction of propagation for each monocrystalline diamond seed, a second value describing the angle giving the direction of propagation of a main wave front of the plurality of monocrystalline diamond seeds and wherein during the step of positioning the monocrystalline diamond seeds so as to form a mosaic, each monocrystalline diamond seed (10, 11, 12, 13) comprises angles giving the directions of propagation (D₁₀, D₁₁) of the wave fronts (FO₁₀, FO₁₁) ranging from −5° to +5° relative to the second value, preferably from −2.5° to +2.5°.
said method comprising a step of surfacing, by lithography or by laser, the crystallographic orientation faces of the monocrystalline diamond seeds so that said seeds have substantially identical angles giving the propagation direction of the wave fronts. In particular, the surfacing step concerns monocrystalline diamond seeds comprising families of planes {100} or crystallographic orientation faces (OC1, OC2) of monocrystalline diamond seeds (10, 11, 12, 13) comprising families of planes {100} and {113}. Preferably, the surfacing step is carried out by laser.
said method comprising a step of resurfacing by laser or by lithography of the monocrystalline diamond plate after removal of the monocrystalline diamond epitaxial layer, the resurfacing step comprising:
   a removal of a predetermined thickness of the monocrystalline diamond plate,
   a formation of a new predetermined terraced structure having crystallographic orientation faces of monocrystalline diamond seeds comprising families of planes {100} or crystallographic orientation faces of monocrystalline diamond seeds comprising families of planes {100} and {113}. Preferably, the surfacing step is carried out by laser. More preferably, the resurfacing step comprises the formation of a new structure in predetermined terraces having crystallographic orientation faces of the monocrystalline diamond seeds comprising families of planes {100} and {113}. This new terraced structure is preferably made on the monocrystalline diamond plate, on the surface created during the removal step.
wherein the seeds of the new terraced structure, formed during the resurfacing step by laser or by lithography, have angles giving the direction of propagation of the substantially identical wave fronts.
wherein the lateral epitaxial growth of the terraced structure according to the crystallographic orientation of the monocrystalline diamond seeds comprises a step of introducing a suitable gas to prevent the development of stresses or the formation of crystalline defects, preferably twins and dislocations, at the interface between the seeds.
wherein the terraced structure comprises macroscopic growth steps. In particular, the terraced structure of the monocrystalline diamond seeds can comprise growth steps whose height is for example at least 100 nm. This improves the junctions and the properties of the diamond layer produced. Furthermore, the macroscopic growth terraces can have lengths L₁₀, L₁₁ of at least 10 μm.
said method comprising a step of creating centers “XV-”, by doping with a suitable gas “X” followed by electron beam irradiation and annealing. This step is preferably carried out after the lateral epitaxial growth step and/or the vertical epitaxial growth step.
wherein the positioning step further comprises placing a monocrystalline diamond seed with respect to another monocrystalline diamond seed at a distance of at most 200 μm.
wherein the terraced structures of the monocrystalline diamond seeds have, with respect to each other, a first planar disorientation along a horizontal axis and a second planar disorientation along a vertical axis less than an angle of 3°.
wherein each monocrystalline diamond seed has a thickness difference of at most 50 μm, preferably at most 30 μm, relative to another adjacent monocrystalline diamond seed. However, monocrystalline diamond seeds may have a difference in thickness of at least 10 μm, for example at least 20 μm, relative to another adjacent monocrystalline diamond seed.
wherein the monocrystalline diamond seeds are positioned in order of increasing thickness according to a direction of propagation defined by one of the angles of the wave fronts. Thus, the mosaic may include seeds having differences in thickness of at least 30 μm, for example of at least 50 μm.
wherein the monocrystalline diamond seeds are positioned in order of decreasing thickness according to a direction of propagation defined by one of the angles of the wave fronts.

According to a second object, the invention relates to a monocrystalline diamond plate comprising a plurality of monocrystalline diamond seeds which include a growth surface, said growth surface comprising a terraced structure, said terraced structure having several crystallographic orientation faces, said crystallographic orientation faces including families of planes {100} or families of planes {100} and {113}, a disorientation angle of the terraced structure greater than or equal to 0° and less than or equal to 10°, and monocrystalline junctions which link the monocrystalline diamond seeds together, the monocrystalline junctions having been obtained by:
a step of positioning the monocrystalline diamond seeds so as to form a mosaic, so that two adjacent monocrystalline diamond seeds have first values describing the angles giving the directions of propagation of the wave fronts whose difference is less than or equal to 5°, preferably substantially equal to 0°; and
a step of lateral epitaxial growth of the terraced structure according to the crystallographic orientation, by enhanced chemical vapor deposition, preferably by plasma or by hot filament, of a monocrystalline layer.

In the same way, the diamond plate according to the invention has expected properties even when two adjacent monocrystalline diamond seeds have first values describing the angles giving the directions of propagation of the wave fronts whose difference is greater than 0°.

According to other optional characteristics of the monocrystalline diamond plate, the latter may optionally include one or more of the following characteristics, alone or in combination:
wherein at least 15%, preferably at least 50% and even more preferably at least 85%, of the junctions formed between the monocrystalline diamond seeds have a width value of Raman peak at half-height greater than or equal to 2.5 cm⁻¹ and less than 2.9 cm⁻¹.

According to a third object, the invention relates to a monocrystalline diamond wafer formed by removing the monocrystalline diamond epitaxial layer obtained by the method according to the invention.

According to another aspect, the invention also relates to a monocrystalline diamond having a surface including at least a first crystallographic face and a second crystallographic face, said crystallographic faces each being associated with a concentration of centers “XV-” and the concentration of centers “XV-” of the first crystallographic face being greater than the concentration of centers “XV-” of the second crystallographic face. In particular, in the monocrystalline diamond according to the invention, the first crystallographic face of the monocrystalline diamond belongs to the family of planes {113}. As will be described, such a monocrystalline diamond can be obtained by a method according to the invention.

According to a fourth object, the invention relates to a use of a monocrystalline diamond plate according to the invention, of a monocrystalline diamond according to the invention, or of a monocrystalline diamond wafer according to the invention for the manufacture of an optical window, a substrate for a semiconductor or for thermal management, a substrate for quantum technologies, or a diamond for jewelry, preferably greater than 5 carats, preferably greater than 15 carats.

### BRIEF DESCRIPTION OF THE DRAWINGS

Other characteristics and advantages of the invention will be better understood upon reading the description which follows and with reference to the appended drawings, given in an illustrative and non-limiting manner.

FIG. 1 shows a diagram of a method for manufacturing a monocrystalline diamond plate according to the invention. Steps framed in dotted lines are optional.

FIG. 2 shows a graphical illustration of a cross-section of a monocrystalline diamond seed viewed from the side.

FIG. 3 shows a graphical illustration of a cross-section of a monocrystalline diamond plate viewed from the side after growth of a monocrystalline diamond layer.

FIG. 4 shows a first graphical illustration of a cross-section of two monocrystalline diamond seeds seen from the side.

FIG. 5 shows an illustration of a monocrystalline diamond seed in a perspective view.

FIG. 6 shows a diagram of a monocrystalline diamond seed seen from above whose flow of steps takes place along OC2, OC2 belonging: a) either to the family of planes {113}, b) or to the family {100}.

FIG. 7 shows a diagram of a mosaic comprising nine monocrystalline diamond seeds seen from above.

FIG. 8 shows a graphic illustration of four monocrystalline diamond seeds seen from above.

FIG. 9 shows a second graphic illustration of a cross-section of two monocrystalline diamond seeds seen from the side.

FIG. 10 corresponds to a photo of a part of a monocrystalline diamond plate according to the invention seen from above.

The figures do not necessarily respect the scales, in particular in thickness, for purposes of illustration.

Aspects of the present invention are described with reference to flowcharts and/or block diagrams of methods according to embodiments of the invention.

In the figures, flow charts and block diagrams illustrate the architecture, functionality and operation of possible implementations of systems, methods according to various embodiments of the present invention. In this regard, each block in the flowcharts or block diagrams may represent a system, device, module or code, which comprises one or more executable instructions to implement the specified logic function(s). In some implementations, the functions associated with the blocks may appear in a different order than shown in the figures. For example, two blocks shown in succession may, in fact, be implemented substantially simultaneously, or the blocks may sometimes be implemented in reverse order, depending on the functionality involved. Each block of the block diagrams and/or the flowchart, and combinations of blocks in the block diagrams and/or the flowchart, may be implemented by special hardware systems that perform the specified functions or acts or perform combinations of special equipment and computer instructions.

### DESCRIPTION OF EMBODIMENTS

Below, a summary of the invention and the associated vocabulary is described, before presenting the disadvantages of the prior art, then finally showing in more detail how the invention overcomes them.

In the remainder of the description, the expression “monocrystalline diamond plate” may correspond to at least two monocrystalline diamond seeds linked together after a first crystal growth.

The expression “large size” within the meaning of the invention may correspond to a plate or wafer having a growth surface greater than 2 cm², preferably greater than 3 cm², preferably greater than 5 cm², even more preferably greater than 10 cm², preferentially greater than 20 cm², and preferably greater than 315 cm².

The term “seed” within the meaning of the invention may correspond to the elements on which the diamond layers or films grow. For monocrystalline layers, these are natural diamond monocrystals or which are produced by high pressure-high temperature (HPHT) method or else produced by CVD (for chemical vapor deposition or chemical vapor deposition enhanced by plasma or hot filament) process.

The term “junction” can refer to a part that physically connects two seeds to each other.

When the term “crystallographic orientation face of the family” is used, it generally refers to a family of crystalline planes. The crystalline planes which have a particular crystalline form whose surface is substantially flat and limiting a crystal, which is denoted by convention between braces. This includes all positional variations that the crystallographic orientation face can take in a crystal. As an example, the family of the crystallographic orientation face of the family {100} also includes positive and negative variants, such as crystallographic faces (010) and (001); similarly, the family of the crystallographic orientation face of the family {113} also includes positive and negative variants, such as crystallographic faces (131) and (311). These crystallographic faces are conventionally defined by three Miller indices denoted between brackets “(hkl)”, h, k and l possibly being positive or negative integers.

A “terraced structure” according to the invention may correspond to a stepped structure comprising steps characterized by a first crystallographic orientation and terraces characterized by a second crystallographic orientation, the second crystallographic orientation is preferably different from the first crystallographic orientation. The steps of a terraced structure are substantially linear and parallel to each other, while the terraces are substantially linear and parallel to each other. By way of illustrative example, the terraces are formed by crystallographic orientation faces of the family {100} of planes and the steps by crystallographic orientation faces of the family {113} of planes of the terraced structure. They can for example form therebetween angles of 154.8° or 107.5°.

The term “growth” within the meaning of the invention may correspond to the step or steps of depositing carbon in the sp3 form of crystalline (monocrystalline) diamond contributing to the production of a monocrystalline diamond layer. The growth conditions and deposition parameters represent a set of variable values: pressure, injected microwave power, total gas flow rate, carbon precursor flow rate, impurities and dopant flow rate, thermal resistance gas composition and their flow rate, temperatures of the growing layer or layers for a given reactor.

The term “diamond” within the meaning of the invention may correspond to one or more monocrystalline diamond layers of varying thickness, resulting from the deposition of carbon in the sp3 form of crystalline (monocrystalline) diamond.

The expression “diamond layer” within the meaning of the invention may correspond to a layer (or a film) of monocrystalline, polycrystalline, nanocrystalline or ultra-nanocrystalline diamond formed after nucleation on a surface of monocrystalline diamond or of another material. Within the meaning of the invention, the production of monocrystalline diamond is generally done by thickening in height and/or width of a strain (or seed) diamond monocrystal originating from a monocrystal of natural diamond or produced by a high-pressure-high temperature (HPHT) method or produced by CVD (for “chemical vapor deposition” enhanced by plasma or by hot filament).

The term “plasma” within the meaning of the invention may correspond to the production, from an electric discharge in a gas composed of a mixture, of a globally electrically neutral medium but containing ions and electrons as well as fragments of dissociated gas species as well as stable molecules.

The expression “disorientation of the terraced structure” (noted δ), within the meaning of the invention, can correspond to the presence of a disorientation angle characterizing the inclination of the terraced structure, more particularly of a terrace formed by a crystallographic orientation face, for example of the family of planes {100}, with respect to the rear face of a monocrystalline diamond seed.

The term “substantially” within the meaning of the invention means a value varying by less than 30% with respect to the compared value, preferably by less than 20%, even more preferably by less than 10%. When substantially identical is used to compare shapes then the vectorized shape varies by less than 30% with respect to the compared vectorized shape, preferably by less than 20%, even more preferably by less than 10%. In particular, when substantially identical is used to compare angles then the angle values are not different by more than 10°, preferably by more than 5°, even more preferably by more than 2° and even more preferred by more than 1°.

For numerous industrial applications, large-size monocrystalline diamond layers (for example more than 20 centimeters in diameter) are expected. Many methods have already been proposed for producing large-size monocrystalline diamond layers. However, monocrystalline diamonds obtained by these methods generally have crystalline defects when the size increases. The applicant has developed a new method allowing to reduce these crystalline defects.

The applicant proposes to use monocrystalline diamond seeds which have crystallographic orientation faces of the family of planes {100} and preferably of the family of planes {100} and {113} in order to generate a high quality and large-size monocrystalline diamond plate by taking into consideration the structural characteristics of each seed and positioning them at an angle of propagation of a wave front. This allows the formation of high quality junctions, that is to say with few or no crystalline defects between the monocrystalline diamond seeds. In particular, the invention proposes to carry out a first growth generated by conditions favoring the lateral growth of the crystallographic orientation faces of the family of planes {113} in order to ensure the formation of a monocrystalline layer of optimal quality between the seeds thus limiting the formation of crystalline defects and the risk of cracking during the growth or cutting of a monocrystalline diamond wafer.

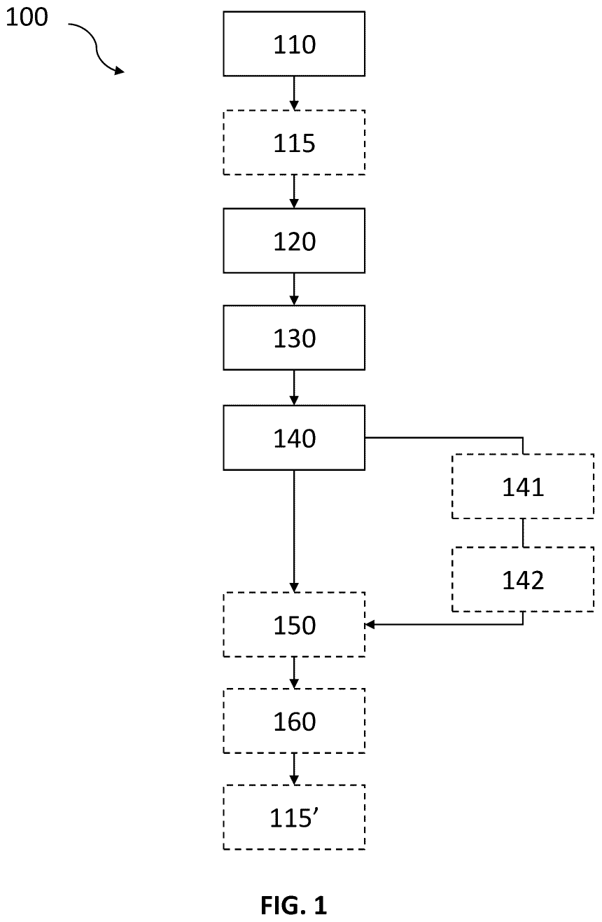

Thus, as illustrated in FIG. 1, the invention relates to a method 100 for producing a large-size monocrystalline diamond plate from a plurality of monocrystalline diamond seeds, the method comprises a step 110 of supplying monocrystalline diamond seeds associated with structural characteristics, a step 130 of positioning the monocrystalline diamond seeds, and a step of lateral epitaxial growth 140.

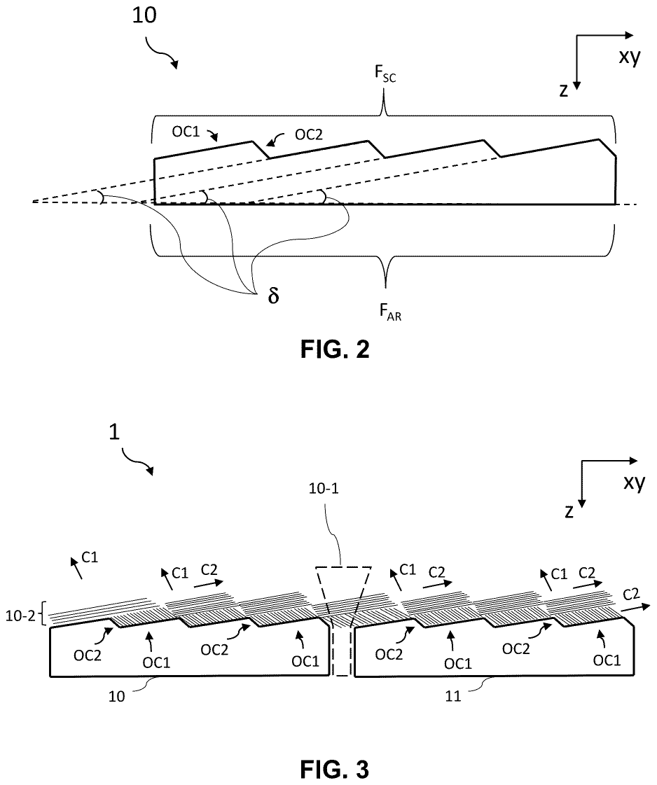

A monocrystalline diamond seed 10 is shown in FIG. 2. The monocrystalline diamond seed 10, and more generally the monocrystalline diamond seeds 11, 12, 13 according to the invention, comprise at least one face F_{sc} constituting the growth surface of the crystal which is made up of crystal planes formed by crystallographic orientation faces OC1 and OC2, respectively the terraces and the steps of the terraced structures. The seed also comprises a rear face F_{AR}, opposite the face F_{sc} constituting the growth surface of the crystal, on which said seed 10 rests during a growth step. The faces of the terraces OC1 of the growth surface F_{sc} and the rear face F_{AR} are substantially parallel. However, they form an angle d₁₀ therebetween, called the disorientation angle.

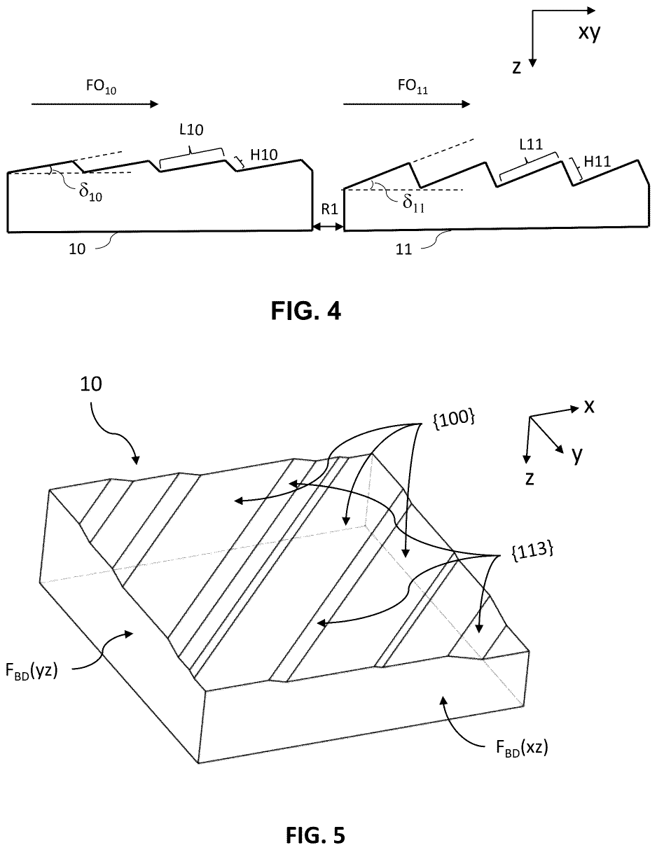

As detailed in FIG. 3, the monocrystalline diamond seed 10 therefore comprises on the surface a stepped structure or terraced structure which has crystallographic orientation faces OC1, OC2 of the family of planes {100} or of the family of planes {100} and {113}. As shown in FIG. 4, the terraced structure of the monocrystalline diamond seeds 10, 11 comprises crystallographic orientation faces OC1 and OC2 which have a predetermined surface. More particularly, the terraced structures of the monocrystalline diamond seeds 10, 11 comprise steps of predetermined width L₁₀, L₁₁ and height H₁₀, H₁₁. Indeed, as shown in FIG. 4, the terraced structures of the monocrystalline diamond seeds 10, 11 used for the formation of a monocrystalline diamond plate should preferably have disorientation angles δ₁₀, δ₁₁ that are substantially identical or at the very least relatively close, they can for example be comprised between 0° and 10°.

The disorientation angles δ₁₀δ₁₁, are for example at least 0.1°, preferably at least 0.5°, more preferably at least 1°, even more preferably at least 2°. The disorientation angles δ₁₀δ₁₁, are for example at most 9.9°, preferably at most 9.5°, more preferably at most 9°, even more preferably at most 8°. Thus, the disorientation angles δ₁₀δ₁₁ are for example comprised between 0.1° and 9.9°, preferably between 0.5° and 9.5°, more preferably between 1° and 9°, even more preferably between 2° and 8°.

As mentioned, within the same seed it is possible to observe different disorientation angles. Advantageously, the disorientation angles within the same seed must not be very different. Thus, preferably, a monocrystalline diamond seed used in the context of the present invention will have a variance of disorientation angles of at most 10%, more preferably of at most 5%, even more preferably of at most 1%.

More particularly, as illustrated in FIGS. 4 and 5, the terraced structure of monocrystalline diamond seeds may comprise macroscopic growth steps, for example which have a height H₁₀, H₁₁ of at least 100 nm and up to at 5 μm.

The terraced structure of the monocrystalline diamond seeds may comprise growth steps whose height is for example at least 100 nm, preferably at least 200 nm, more preferably at least 500 nm, even more preferably at least 1000 nm. The height of the growth steps is for example at most 4.5 μm, preferably at most 4 μm, more preferably at most 3.5 μm, even more preferably at most 3 μm. Thus, the heights of the growth steps are for example comprised between 100 nm and 4.5 μm, preferably between 200 nm and 4 μm, more preferably between 500 nm and 3.5 μm, even more preferably between 1000 nm and 3 μm. The heights of the growth steps can vary within a seed. Thus, the above values may correspond to median values observed on a seed.

Preferably, a monocrystalline diamond seed used in the context of the present invention will have a variance of the heights of the growth steps of less than 30%, more preferably less than 20%, even more preferably less than 10%.

Furthermore, the macroscopic growth terraces OC1 can have lengths L₁₀, L₁₁ comprised between 10 μm and 300 μm.

The terraced structure of the monocrystalline diamond seeds may comprise growth terraces whose length is for example at least 10 μm, preferably at least 20 μm, more preferably at least 30 μm, even more preferably at least 50 μm. The length of the growth terraces is for example at most 300 μm, preferably at most 250 μm, more preferably at most 200 μm, even more preferably at most 150 μm. Thus, the lengths of the growth terraces are for example comprised between 10 μm and 300 μm, preferably between 20 μm and 250 μm, more preferably between 30 μm and 200 μm, even more preferably between 50 μm and 150 μm. The lengths of the growth terraces may vary. Thus, the above values may correspond to median values observed on a seed.

Preferably, a monocrystalline diamond seed used in the context of the present invention will have a variance of the lengths of the growth terraces of less than 30%, more preferably less than 20%, even more preferably less than 10%.

A method in accordance with the invention thus comprises a step 110 of supplying monocrystalline diamond seeds 10, 11, 12, 13, each of the seeds being associated with structural characteristics. In the context of the invention, the structural characteristics comprise at least a first value describing an angle giving a direction of propagation D₁₀ of the wave front FO₁₀.

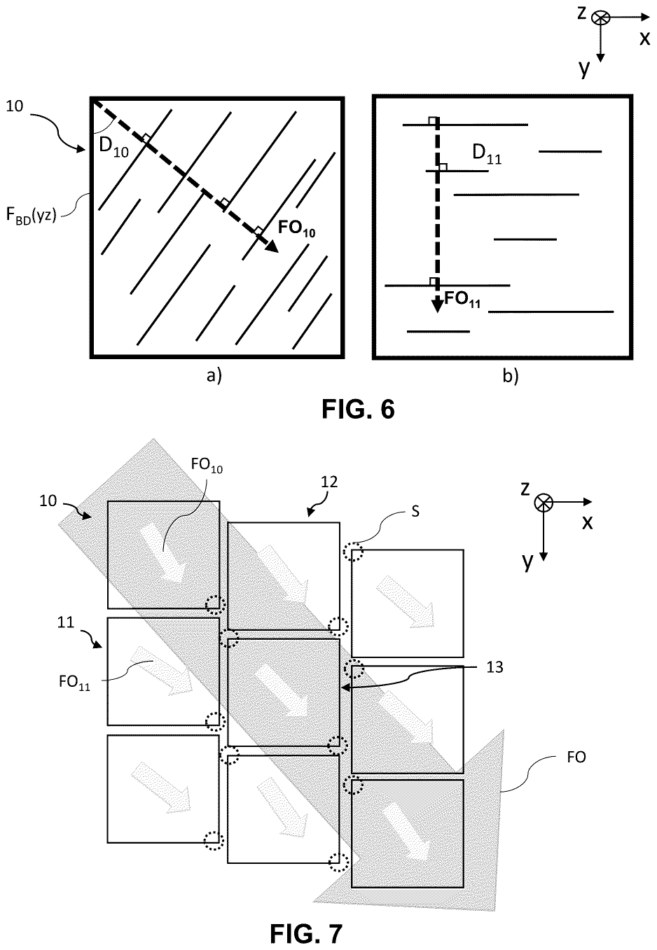

Such an angle can be formed by the direction of movement of the steps or of the crystallographic orientation faces OC2 and the axes x or y, of the lateral faces F_{BD} of the seed 10 of monocrystalline diamond, oriented as indicated in FIGS. 5 and 6. The value of the angle D₁₀ thus allows to define the direction of propagation of the wave front FO₁₀, representing the movement of the step fronts or crystallographic orientation faces OC2, which are called Wave front as shown in FIG. 6.

A method in accordance with the invention may further comprise a step of determining (not shown in the figures) the structural characteristics of each monocrystalline diamond seed 10, 11, 12, 13 previously mentioned.

As illustrated in FIG. 7, for each of the seeds, a first value describing an angle D₁₀, D₁₁ giving a direction of propagation of the wave front FO₁₀ is provided. The angles D₁₀, D₁₁ are defined such that they belong to the interval [0, π/2]. During diamond growth by microwave plasma enhanced deposition, the wave fronts move at a very specific angle, sense and direction along the terraced structure of each monocrystalline diamond seed.

The structural characteristics also comprise a disorientation angle δ, of the terraced structure, greater than or equal to 0° and less than or equal to 10° with respect to the rear face F_{AR}. Advantageously, the disorientation angle is strictly greater than 0°. Furthermore, when the disorientation angle is greater than 0° but less than or equal to 10°, growth by step flow mechanism occurs and this allows to limit the appearance of crystalline defects during the growth steps, and more particularly the formation of twins.

In addition, the structural characteristics may comprise the dimensions of the growth steps of the terraced structure, the direction of propagation of the wave front and/or the thickness of each monocrystalline diamond seed 10, 11, 12, 13.

To determine the structural characteristics of monocrystalline diamond seeds 10, 11, 12, 13, known techniques such as optical or digital microscopy, electron backscatter diffraction which allows microstructural and crystallographic characterization via a scanning electron microscope can for example be used. This provides information about the structure, crystallographic orientation, phase, or strain in the material.

Furthermore, it is possible to measure the crystallographic orientation of the faces of the seeds by electron microscopy techniques in order to provide only the seeds which have faces of the same crystallographic orientation.

The production method 100 can also comprise a step 120 of calculating, from the values describing an angle giving the direction of propagation D₁₀, D₁₁, supplied for each monocrystalline diamond seed 10, 11, 12, 13, a second value describing the angle giving the direction of propagation of the main wave front FO of the plurality of monocrystalline diamond seeds 10, 11, 12, 13.

By way of non-limiting example, the calculation step 120 can be implemented by a computer or more generally by any type of computer device configured for this purpose.

In a first embodiment, the production method 100 according to the invention may comprise a step 115 of surfacing, by lithography or by laser, the crystallographic orientation faces OC1, OC2 of the families of planes {100} or families of planes {100} and {113} of monocrystalline diamond seeds 10, 11, 12, 13 so that said seeds have angles giving the directions of propagation D₁₀, D₁₁ of the wave fronts FO₁₀, FO₁₁ which are substantially identical. Thus, this allows to limit the appearance of crystalline defects during the growth steps.

By way of non-limiting example, the surfacing step 115 can be implemented by a laser, such as a laser guided by a water jet, for example 50 μm in diameter, with a wavelength of 532 nm, with a power of 50 W and a frequency of 6 kHz. In particular, the surfacing step 115 can be implemented by a laser having a diameter of at least 10 μm, preferably of at least 20 μm, more preferably of at least 30 μm and more preferably at least 50 μm in diameter. The surfacing step 115 can be implemented by a laser having a diameter of at most 200 μm, preferably of at most 150 μm, more preferably of at most 125 μm and more preferably of at most 100 μm in diameter.

The surfacing step 115 can be performed by scanning the laser over the surface of the monocrystalline diamond plate. The surfacing step 115 can alternatively be implemented by lithography, in particular by using a photolithography mask comprising patterns to be produced on the surface of the diamond. A step of depositing SiO₂ in a PECVD (plasma-enhanced chemical vapor deposition) frame then a photosensitive resin precedes the photolithography. Then, a step of etching, in a frame for reactive ionic etching, the deposition of SiO₂ then the diamond allows to complete the resurfacing.

The production method 100 according to the invention further comprises a step 130 of positioning the monocrystalline diamond seeds, so as to form a mosaic. The monocrystalline diamond seeds are positioned so that two adjacent monocrystalline diamond seeds have first values describing the angles giving the directions of propagation D₁₀, D₁₁ of the wave fronts FO₁₀, FO₁₁ whose difference is preferably substantially equal to 0°, more preferably equal to 0°.

The monocrystalline diamond seeds are positioned so that two adjacent monocrystalline diamond seeds have first values describing the angles giving the propagation directions D₁₀, D₁₁ of the wave fronts FO₁₀, FO₁₁, the difference of which is at most 5°.

The monocrystalline diamond seeds are positioned so that two adjacent monocrystalline diamond seeds have first values describing the angles giving the propagation directions D₁₀, D₁₁ of the wave fronts FO₁₀, FO₁₁ whose difference is greater than or equal to at 0° and less than or equal to 5°.

The monocrystalline diamond seeds can be positioned so that two adjacent monocrystalline diamond seeds have first values describing the angles giving the directions of propagation D₁₀, D₁₁ of the wave fronts FO₁₀, FO₁₁ whose difference is less than or equal to 4°, preferably less than or equal to 3°, preferably less than or equal to 2° and even more preferably less than or equal to 1° and even more preferably equal to 0°.

In one embodiment, the positioning 130 of the monocrystalline diamond seeds can be carried out in the same direction of propagation of the wave front FO₁₀, FO₁₁, so as to form a mosaic, each monocrystalline diamond seed 10, 11, 12, 13 comprising an angle giving the direction of propagation D₁₀, D₁₁, of the wave front FO₁₀, FO₁₁ whose difference is greater than or equal to 0° and less than or equal to 5° with respect to the second value describing the angle giving the direction of propagation of the main wave front FO of the plurality of monocrystalline diamond seeds 10, 11, 12, 13 constituting the mosaic.

Optionally, as shown in FIG. 7, the monocrystalline diamond seeds 10, 11, 12, 13 can be of parallelepiped shape, more particularly of square shape, or even octahedral or even triangular. They can further be positioned offset from each other, so that at least one vertex S of each monocrystalline diamond seed 10, 11, 12, 13 is positioned opposite each other with respect to a side of an adjacent monocrystalline diamond seed. Thus, the vertices S of the seeds are in contact or not and opposite each other with a maximum of two adjacent seeds. This allows to limit the generation of mechanical stresses during the growth steps.

In order to obtain high-quality junctions and enable the manufacture of a large-size monocrystalline diamond plate, the monocrystalline diamond seeds may have a difference in thickness of at most 50 μm, preferably at most 30 μm, relative to another adjacent monocrystalline diamond seed.

In order to further improve the formation of high quality junctions and to allow the manufacture of a large-size monocrystalline diamond plate, the monocrystalline diamond seeds can be positioned in order of increasing thickness according to a direction of propagation defined by one of the angles D₁₀, D₁₁ of the wave fronts FO₁₀, FO₁₁. More particularly, the monocrystalline diamond seeds are positioned so as to have a difference in thickness which increases with respect to one or more of the adjacent seeds, in the sense of the directions of propagation of the wave fronts FO₁₀, FO₁₁ given by their angles D₁₀D₁₁. By way of illustrative example, the monocrystalline diamond seeds, which form the mosaic and which have a first minimum thickness E1 can be positioned first in the sense of the directions of propagation of their wave fronts, of associated angles D₁₀, D₁₁ then the monocrystalline diamond seeds which have a second thickness E2 increasing by less than 5 μm difference with respect to the first thickness E1 can be positioned adjacent to the monocrystalline diamond seeds which have such a first thickness E1. Finally, the monocrystalline diamond seeds which have an increasing thickness, for example a third thickness E3 of more than 5 μm and up to 50 μm difference with respect to the adjacent seeds, are positioned following, adjacent to the monocrystalline diamond seeds which have a second thickness E2 increasing by less than 5 μm difference with respect to the first thickness E1 in the sense of the direction of propagation defined by one of the angles D₁₀, D₁₁ of the wave fronts FO₁₀, FO₁₁. Thus, the difference in thickness between each adjacent monocrystalline diamond seed is preferably less than or equal to 30 μm, more preferably less than or equal to 25 μm, even more preferably less than or equal to 20 μm, and for example less than or equal to 15 μm.

Optionally, the positioning step 130 can further comprise placing a monocrystalline diamond seed relative to another monocrystalline diamond seed at a distance R1 of at most 200 μm, preferably of at most 150 μm, more preferably at most 100 μm, even more preferably at most 50 μm.

Still in the invention, the method 100 for producing a large-size monocrystalline diamond plate comprises a step of depositing a monocrystalline diamond layer on the mosaic, this deposition step includes one or more epitaxial growth steps. The step of depositing a monocrystalline diamond layer on the mosaic may comprise the injection of a gas under predetermined pressure, flow rate and temperature conditions. For this purpose, the mosaic is, for example, positioned in a microwave plasma-enhanced deposition reactor of known type, for example under the following conditions: 200 mbar, 21 KW, 2000 sccm of H₂, 5% CH4, and at a growth temperature ranging from 1000 °C to 1060 °C. By way of non-limiting example, the microwave plasma-enhanced deposition reactor may comprise:
a resonant cavity formed at least in part by the cylindrical internal walls of an enclosure of the reactor,
a treatment gas supply system capable of providing treatment gases within the resonant cavity,
a microwave generator configured to generate microwaves whose frequency is comprised between 300 MHz and 3000 MHz,
a gas outlet module capable of removing said gases from the resonant cavity,
a wave coupling module capable of transferring the microwaves from the microwave generator to the resonant cavity, so as to allow the formation of a homogeneous plasma at the plasma/surface interface,
a growth support present in the resonant cavity,
a surface growth temperature control module.

In particular, the production method 100 according to the invention comprises a step of lateral epitaxial growth 140 of the terraced structure according to the crystallographic orientation OC2 of the face of families of planes {100} when the seeds comprise families of planes {100} only or of the family of planes {113} when the seeds comprise families of planes {100} and {113}, by plasma-enhanced chemical vapor deposition of a monocrystalline layer.

The lateral epitaxial growth step 140 can be implemented in a plasma-enhanced deposition reactor of known type at predetermined conditions to allow a growth C2 according to the crystallographic orientation OC2 as shown in FIG. 3.

Preferably, the epitaxial growth step 140 includes an epitaxial growth according to the crystallographic orientation OC2 of the face of the family of planes {113}. Indeed, it allows the formation of monocrystalline junctions 10-1, between two monocrystalline diamond seeds 10, 11, of high quality as presented in the examples.

The lateral epitaxial growth step 140 may optionally be carried out by means suitable for hot wire enhanced chemical vapor deposition.

As an illustrative example, the growth conditions during the lateral epitaxial growth step 140 may comprise the generation of a pressure comprised between 20 hPa and 500 hPa within the resonant cavity, the injection of microwaves at a power comprised between for example 0.5 KW and 100 KW (or more), depending on the type of generator used (frequency used), gas injection, for example at a total flow rate of at least 150 standard cm³ per minute (sccm), the gases comprising for example methane, argon and dihydrogen or a mixture of all or part of these gases, and additives such as oxygen, nitrogen, boron, phosphorus and argon, or else halogens and the operation of cooling systems of the enclosure, the substrate to control the temperature of the growth surface(s) in a range preferably from 800 °C to 1200 °C, the gas injection system and the substrate holder.

In a particular embodiment of the production method 100 according to the invention, the step of lateral epitaxial growth 140 of the terraced structure according to the crystalline orientation OC2 of the monocrystalline diamond seeds 10, 11, 12, 13 comprising families of planes {100} or monocrystalline diamond seeds 10, 11, 12, 13 comprising families of planes {100} and {113}, may comprise a step of introducing 141 a suitable gas to prevent the development of stresses and the formation of twins at the interface between the seeds 10, 11, 12, 13. Such a gas can for example be introduced by a gas supply system to allow a supply of nitrogen into the resonant cavity, for example at a concentration of at most 250 ppm of nitrogen, preferably of at most 10 ppm of nitrogen, preferably of at most 3 ppm of nitrogen. The use of nitrogen, at a content of for example at least 1 ppm, for example during the lateral epitaxial growth step 140 allows to limit the development of crystalline defects, in particular twins, and ensures greater crystalline stability.

In a particular embodiment of the production method according to the invention, the lateral epitaxial growth step 140 may further comprise a step 142 of creating colored centers called centers “XV-”, followed by electron beam irradiation and annealing. For this purpose, the step of creating 142 centers XV-comprises the introduction, by a gas supply system, to allow a supply of doping gas “X”, such as by way of non-limiting examples nitrogen or silicon, into the resonant cavity, for example at a concentration of 10 ppm to 1000 ppm of nitrogen. The use of such so-called doping gases allows to modify the properties of the synthesized diamond. This can, for example, modify its optical, electronic and quantum properties. Advantageously, the creation step 142 can be carried out during lateral epitaxial growth of the terraced structure according to the crystallographic orientation OC2 of the face of the family of planes {113}.

In another particular embodiment of the production method according to the invention, the latter may comprise a second step of lateral epitaxial growth further comprising the creation 142 of centers “XV-” as described previously. Preferably, this step of creating 142 centers “XV-” will be carried out after a surfacing step.

In a production method 100 according to the invention, the step of lateral epitaxial growth 140 of the terraced structure which allowed the formation of the junctions by lateral movement of the planes OC2, can be followed by a second vertical epitaxial growth 150 according to the crystallographic orientation OC1 of the face of the family of planes {100} of the monocrystalline diamond seeds 10, 11, 12, 13 comprising families of planes {100} or monocrystalline diamond seeds 10, 11, 12, 13 comprising families of planes {100} and {113}, which allows vertical growth to form a monocrystalline diamond epitaxial layer 10-2. The vertical growth step 150 of the terraced structure according to the crystallographic orientation OC1 of the family of planes {100} can be implemented in a microwave plasma-enhanced deposition reactor as described above, at predetermined conditions to promote growth C1 according to the crystallographic orientation OC1 as shown in FIG. 3. The flow growth mechanism of the steps (movement of the wave fronts from one seed to another) allows the formation of high quality monocrystalline junctions 10-1, between two monocrystalline diamond seeds 10, 11. The vertical epitaxial growth step 150 according to the crystallographic orientation OC1 of the face of the family of planes {100} also proceeds according to this mechanism, and the crystal grows according to C1 (vertically) and according to C2 (laterally) although the growth conditions are adapted to promote vertical or lateral growths, which are more marked according to the orientations OC1 and OC2.

When the production method 100 according to the invention comprises a second vertical epitaxial growth 150, it may also require a step 160 of removing the monocrystalline diamond epitaxial layer 10-2. The removal step 160 may consist of cutting with a laser of known type or another method, for example of the lift-off type.

As already mentioned, one of the objectives of the invention is to produce a monocrystalline diamond plate 1 which has high quality junctions. Another object of the invention is to allow the reuse of said monocrystalline diamond plate 1 once produced. For this purpose, the step 160 of removing the monocrystalline diamond epitaxial layer 10-2 can be followed by a step 115′ of resurfacing by laser or by lithography the monocrystalline diamond plate. The step 115′ of resurfacing by laser or by lithography comprises:
a removal of a predetermined thickness of the monocrystalline diamond plate,
optionally, a polishing step,
a formation of a new predetermined terraced structure having crystallographic orientation faces OC1, OC2 of monocrystalline diamond seeds 10, 11, 12, 13 comprising families of planes {100} or crystallographic orientation faces OC1, OC2 monocrystalline diamond seeds 10, 11, 12, 13 comprising families of planes {100} and {113} or else crystallographic orientation faces OC1, OC2 of monocrystalline diamond seeds 10, 11, 12, 13 comprising families of planes {100} and {110}.

In order to maintain a similar quality for the formation of monocrystalline junctions, the faces of crystalline orientations OC1, OC2 of the families of planes {100} or families of planes {100} and {113} of the new terraced structure are formed according to the angles giving the directions of propagation D₁₀, D₁₁ of the wave fronts FO₁₀, FO₁₁ of the monocrystalline diamond seeds of the positioning step 130.

Thus, the seeds of the new terraced structure, formed during the resurfacing step 115′ by laser or by lithography, have an angle giving the direction of propagation D₁₀, D₁₁ of the wave front FO₁₀, FO₁₁ which is substantially identical.

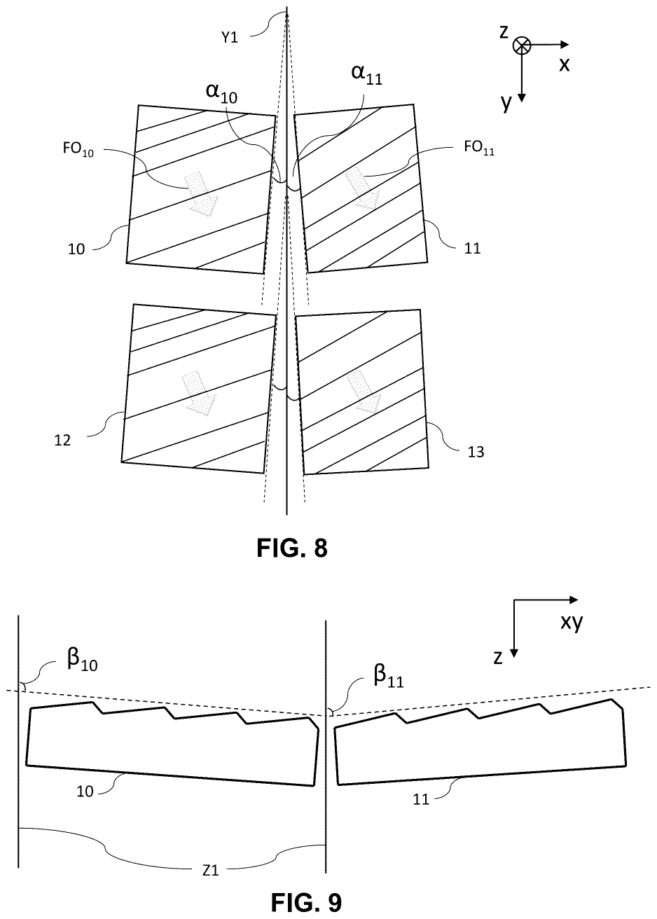

As shown in FIGS. 8 and 9, the monocrystalline diamond seeds of the production method 100 according to the invention may comprise terraced structures which have, relative to each other, a planar disorientation along a horizontal axis Y1 and a planar disorientation along a vertical axis Z1.

The planar disorientations will have an angle α₁₀, α₁₁, β₁₀, β₁₁ of planar disorientation along a horizontal axis Y1 and/or a vertical axis Z1, respectively with respect to the lateral face F_{BD} and/or the face F_{AR} constituting the rear surface of the crystal which will for example be less than 3°, preferably less than 2.5°, more preferably less than 2°, even more preferably equal to 0°. The planar disorientations will have an angle β₁₀, α₁₁ of planar disorientation along a horizontal axis Y1 and/or a vertical axis Z1, respectively with respect to the lateral face F_{BD} and/or the face F_{AR} constituting the rear surface of the crystal which will for example be greater than or equal to 0°, preferably greater than 0.1°, more preferably greater than 0.2°, even more preferably greater than 0.5°. The planar disorientations will have an angle α₁₀, α₁₁ of planar disorientation along a horizontal axis Y1 and/or a vertical axis Z1, respectively with respect to the lateral face F_{BD} and/or the face F_{AR} constituting the rear surface of the crystal which will for example be comprised between 0° and 3°, preferably comprised between 0° and 2.5°, more preferably comprised between 0° and 1°, even more preferably comprised between 0° and 0.5° (limits included). The planar disorientations may alternatively have a planar disorientation angle along a horizontal axis Y1 and/or a vertical axis Z1, respectively with respect to the lateral face F_{BD} and/or the face F_{AR} constituting the rear surface of the crystal comprised between 0.1° and 3°, preferably between 0.2° and 2.5°, more preferably between 0.5° and 1°.

Planar disorientation angles can vary within a mosaic. Thus, the above values of planar disorientation angles may correspond to median values observed on a seed. Preferably, a mosaic used in the context of the present invention will have a variance of the angles of planar disorientations of less than 30%, more preferably less than 20%, even more preferably less than 10% with respect to the median of the planar disorientation angle values.

According to a second object, the invention relates to a monocrystalline diamond plate 1, preferably of large size, capable of being obtained by the present invention. The monocrystalline diamond plate 1 can advantageously be obtained by a production method 100 according to the invention.

In particular, the invention relates to a monocrystalline diamond plate 1, preferably of large size, which includes a growth surface, said growth surface comprising a terraced structure, said terraced structure having several crystallographic orientation faces OC1, OC2, said crystallographic orientation faces OC1, OC2 including families of planes {100} or families of planes {100} and {113}, a disorientation angle (o) of the terraced structure greater than or equal to 0° and less than or equal to 10°, and monocrystalline junctions which connect the monocrystalline diamond seeds 10, 11, 12, 13 to each other, the monocrystalline junctions having been obtained by:
a step of positioning the monocrystalline diamond seeds so as to form a mosaic, so that two adjacent monocrystalline diamond seeds 10, 11, 12, 13 have first values describing the angles giving the propagation directions D₁₀, D₁₁ of the wave fronts FO₁₀, FO₁₁ whose difference is greater than or equal to 0° and less than or equal to 5°, preferably less than or equal to 1°,
a step of lateral epitaxial growth of the terraced structure according to the crystallographic orientation OC2, by enhanced chemical vapor deposition, preferably by plasma or by hot filament, of a monocrystalline layer.

A monocrystalline diamond plate 1 according to the invention comprises junctions, formed between the monocrystalline diamond seeds, wherein at least 15% of the junctions, preferably at least 50%, even more preferably at least 85% have a width value of Raman peak at half-height ranging from 2.4 cm⁻¹ to 2.9 cm⁻¹, preferably substantially equal to 2.5 cm⁻¹.

A monocrystalline diamond plate 1 according to the invention thus allows the formation of a monocrystalline diamond epitaxial layer 10-2 by growth according to the crystallographic orientation OC1 of the family of planes {100}. The quality of the junctions of the monocrystalline diamond plate 1 allows, upon removal of the epitaxial layer 10-2, to obtain a large-size monocrystalline diamond wafer particularly suitable for use in the manufacture of an optical window, a semiconductor substrate, a substrate for thermal management, a substrate suitable for quantum technologies, or a jewelry diamond at least greater than 5 carats, preferably greater than 10 carats, preferably greater than 15 carats. Alternatively, the monocrystalline diamond plate 1 according to the invention could be directly used in the applications mentioned above.

The invention allows to form a monocrystalline diamond, whether a plate or a wafer, having a surface comprising at least a first crystallographic face and a second crystallographic face, said crystallographic faces each being associated with a concentration of center “XV-” and the concentration of center “XV-” of the first crystallographic face being greater than the concentration of center “XV-” of the second crystallographic face. Such a monocrystalline diamond has particularly expected properties. Indeed, while many seek to homogenize the concentration of center “XV” on the surface of monocrystalline diamonds, the present invention is concerned with the centers “XV-” and seeks to create zones of differential concentrations. Furthermore, advantageously, a monocrystalline diamond according to the invention is of large size.

Preferably, the concentrations of centers “XV-” of the crystallographic faces are such that the ratio between the concentration of centers “XV-” of the first crystallographic face and the concentration of centers “XV-” of the second crystallographic face is greater than 1.1; preferably greater than 2; more preferably greater than 5 and even more preferably greater than 10. The concentration of centers “XV-” can be measured using several techniques, for example using photoluminescence measurements with a confocal microscope coupled with a Hanbury-Brown and Twiss interferometer (ref Thesis L. Rondin, HAL Id: tel-00824468, 2013).

The concentration of centers “XV-” of the first crystallographic face is for example greater than 3 ppm, preferably greater than 5 ppm and even more preferably greater than 10 ppm.

Thus, the monocrystalline diamond plate or wafer may have bands enriched in center “XV-” with respect to the adjacent monocrystalline diamond zones. Preferably, the monocrystalline diamond may include at least two bands of at least 10 μm in height having a concentration of center “XV-” greater than the adjacent monocrystalline diamond zones.

These bands may correspond to the first crystallographic face. Preferably, the monocrystalline diamond wafer may include at least two bands of at least 10 μm in height corresponding to the first crystallographic face.

Even if the crystallographic faces can have the same crystallographic orientation (for example family of plane {100}), preferably, the crystallographic faces will have crystallographic orientations of different plane families. Also, the monocrystalline diamond wafer may have bands corresponding to a crystallographic orientation face of a first family of planes and bands corresponding to a crystallographic orientation face of a second family of planes, different from the first family of planes.

Preferably, the monocrystalline diamond may comprise at least two bands corresponding to crystallographic faces having a crystallographic orientation of a first family of planes and at least two bands corresponding to crystallographic faces having a crystallographic orientation of a second family of planes, different from the first family of planes.

Furthermore, advantageously, the first crystallographic face may belong to the family of planes {113} or {110} while the second crystallographic face may belong to the family of planes {100}.

Thus, the monocrystalline diamond may have bands distinct by their concentration of center “XV-” and/or by the family of planes of the orientation of their crystallographic face.

Preferably, the invention therefore relates to a monocrystalline diamond, whether a plate or a wafer, having a surface including at least a first crystallographic face and a second crystallographic face, said crystallographic faces each being associated with a concentration of center “XV-” and the concentration of center “XV-” of the first crystallographic face being greater than the concentration of center “XV-” of the second crystallographic face.

Such a monocrystalline diamond can have the properties described above in connection with the method according to the invention, the plate or the wafer. Advantageously, the first crystallographic face of the monocrystalline diamond belongs to the family of planes {113}.

As illustrated by the examples below, the present invention provides a solution based on the use of a mosaic of selected monocrystalline diamond seeds which have particular structural characteristics and are positioned in a particular way. In particular, the seeds are selected and positioned according to the values of the angles giving the direction of propagation of a wave front. This contributes to the formation of a large-size monocrystalline diamond plate whose junctions are of high quality.

### Examples

### Formation of Reference Monocrystalline Diamond Plates

Fifty monocrystalline diamond seeds measuring 8 mm by 8 mm were selected to form monocrystalline diamond plates measuring 32 cm². The monocrystalline diamond seeds used have the following structural characteristics:
a growth surface that comprises a terraced structure that has crystallographic orientation faces of the families of planes {100} and {113},
a disorientation angle, of the terraced structure, of approximately 3° (with a precision of approximately) 1°.

For each of the monocrystalline diamond seeds, the value of the angle giving the direction of propagation of the wave front is provided.

The different monocrystalline diamond plates presented below are formed by plasma-enhanced chemical vapor deposition as presented in C. Findeling-Dufour and al., Diamond and Related Materials 4 (1995) 428-434 or else in A. Tallaire and al. Growth of large size diamond single crystals by plasma assisted chemical vapour deposition: Recent achievements and remaining challenges/C.R. Physics 14 (2013) 169-184.

### Methodology for Measuring the Quality of the Junctions of Monocrystalline Diamond Seeds:

The measurement of the width of Raman peak at half-height of the monocrystalline diamond plate located at 1332.5 cm⁻¹ is carried out with a laser of wavelength 473 nm with a power of 400 mW with an objective x100 at 298 K. The measurement is made on the surface of the monocrystalline diamond plate, along a line that includes the monocrystalline diamond seeds and their junctions or as described in VG RALCHENKO, and al.; Thermal Conductivity of Diamond Mosaic Crystals Grown by Chemical Vapor Deposition: Thermal Resistance of Junctions; PHYS. REV. APPLIED 16, 014049 (2021).

Junctions are defined by their quality which reflects the presence or absence of crystalline defects. Three types of junctions are defined in order to be able to qualify the overall quality of the monocrystalline diamond plate formed, namely:
Type 1 junction, is characterized by the presence of wave fronts of steps and terraces whose directions may be different from those of adjacent seeds, but also by the presence of crystalline defects such as twins and dislocations. This type of junction is characterized by a width value of Raman peak at half-height greater than 6 cm⁻¹.
Type 2 junction, characterized by the presence of dislocations only. This type of junction is characterized by a width value of Raman peak at half-height ranging from 3 cm⁻¹ to 5.9 cm⁻¹.
Type 3 junction, is characterized by the absence of crystalline defects, more particularly the absence of twins and dislocations. This type of junction is characterized by a width value of Raman peak at half-height greater than or equal to 2.5 cm⁻¹ and less than 2.9 cm⁻¹.

Table 1 below presents the main characteristics concerning the positioning of the various monocrystalline diamond seeds used for the formation of monocrystalline diamond plates as well as the results of the measurement of the quality of the junctions produced for each reference monocrystalline diamond plate, namely:
DIAM 01: the adjacent monocrystalline diamond seeds are positioned randomly, the values of the angles giving the directions of propagation of the different wave fronts are part of a circle (from 0° to) 360°.
DIAM 02: the adjacent monocrystalline diamond seeds are positioned in the same direction of propagation of the wave front, the difference between the values of the angles giving the directions of propagation of the wave fronts of all the monocrystalline diamond seeds is comprised within an interval of + or −45°.
DIAM 03: the adjacent monocrystalline diamond seeds are positioned in the same direction of propagation of the wave front, the difference between the values of the angles giving the direction of propagation of the wave fronts of all the monocrystalline diamond seeds is comprised within an interval of + or −15°. The monocrystalline diamond seeds are positioned in order of decreasing thickness in the direction of propagation of the wave front of one of the seeds of the mosaic.
DIAM 04: the adjacent monocrystalline diamond seeds are positioned in the same direction of propagation of the wave front, the difference between the values of the angles giving the direction of propagation of the wave fronts FO of all the monocrystalline diamond seeds is comprised within an interval ranging from + or − 15°. The monocrystalline diamond seeds are positioned in order of increasing thickness in the direction of propagation of the wave front of one of the seeds of the mosaic.
DIAM 05: the adjacent monocrystalline diamond seeds are positioned in the same direction of propagation of the wave front, the difference between the values of the angles giving the direction of propagation of the wave fronts of all the monocrystalline diamond seeds is comprised in the interval [0°; 5°].

TABLE 1

| | Difference | | | | | |
|---|---|---|---|---|---|---|
| | between | | | | | |
| | values | | | | | |
| | describing | | | | | |
| | the wave | | | | | |
| | front | Increasing | Decreasing | | | |
| | propagation | thickness in | thickness | | | |
| | angle of | the direction | in the | | | |
| | adjacent | of | direction of | Type 1 | Type 2 | Type 3 |
| | monocrystalline | propagation | propagation | Junction | Junction | Junction |
| Plate | diamond | of the wave | of the wave | (% total | (% total | (% total |
| reference | seeds | front | front | junctions) | junctions) | junctions) |
| DIAM01 | ≤180° | No | No | 83 | 13 | 4 |
| DIAM02 | ≤45° | No | No | 42 | 55 | 2 |
| DIAM03 | ≤15° | No | Yes | 27 | 70 | 3 |
| DIAM04 | ≤15° | Yes | No | 20 | 75 | 5 |
| DIAM05 | <0° and ≤5° | No | No | 0 | 85 | 15 |

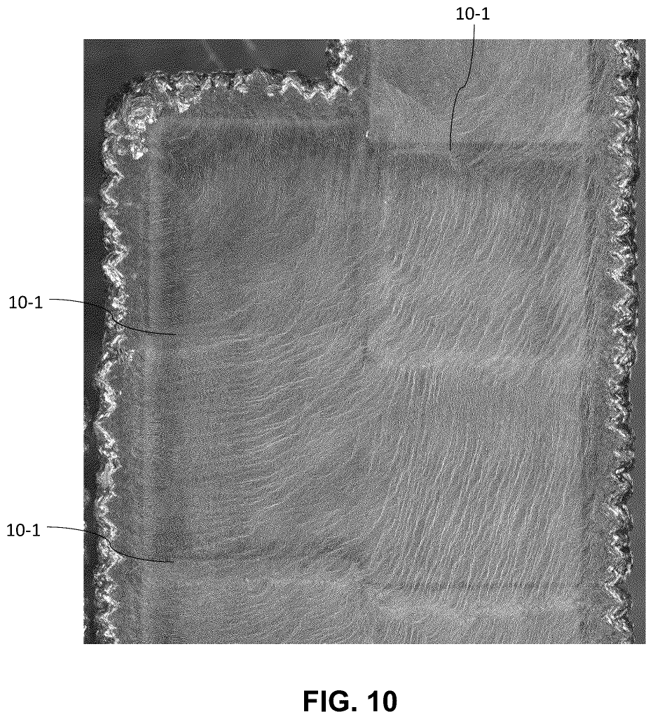

These results show that the positioning of the monocrystalline diamond seeds during the formation of the mosaic is particularly important. Indeed, the results show a very marked improvement in the quality of the junctions of the monocrystalline diamond plates when the monocrystalline diamond seeds have first values describing the angles giving the directions of propagation of the wave fronts whose difference is less than or equal to 5°. FIG. 10 thus shows part of the plate referenced DIAM05, it can be observed with the naked eye that the junctions 10-1 between the plates do not have any crystalline defects.

Furthermore, these results show that the positioning of the monocrystalline diamond seeds according to an increasing or decreasing thickness with respect to the direction of propagation of the wave front allows to improve the quality of the junctions formed.

The invention may be the subject of numerous variants and applications other than those described above. In particular, unless otherwise indicated, the various structural and functional characteristics of each of the implementations described above should not be considered as combined and/or closely and/or inextricably related to each other, but on the contrary as simple juxtapositions. Furthermore, the structural and/or functional characteristics of the various embodiments described above may be the subject, in whole or in part, of any different juxtaposition or any different combination.

1. A method for producing a monocrystalline diamond plate from a plurality of monocrystalline diamond seeds which include a growth surface, said growth surface comprising a terraced structure, said terraced structure having several crystallographic orientation faces (OC1, OC2), said crystallographic orientation faces (OC1, OC2) including families of planes {100} or families of planes {100} and {113}, the method comprising the following steps:
supply of monocrystalline diamond seeds, each of the seeds being associated with structural characteristics, said structural characteristics comprising at least:
a first value describing an angle giving a direction of propagation of a wave front,
a disorientation angle (δ) of the terraced structure greater than or equal to 0° and less than or equal to 10°,
positioning of the monocrystalline diamond seeds so as to form a mosaic, so that two adjacent monocrystalline diamond seeds have first values describing the angles giving the directions of propagation of the wave fronts whose difference is less than or equal to 5°; and
lateral epitaxial growth of the terraced structure according to the crystallographic orientation (OC2), by enhanced chemical vapor deposition of a monocrystalline layer.

2. The production method according to claim 1, wherein the step of lateral epitaxial growth according to the crystallographic orientation (OC2) is followed by a second vertical epitaxial growth of the terraced structure according to the crystallographic orientation (OC1) of the family of planes {100} so as to form a monocrystalline diamond epitaxial layer.

3. The production method according to claim 1, further including a step of calculating, from the first values describing a direction of propagation for each monocrystalline diamond seed, a second value describing the angle giving the direction of propagation of a main wave front of the plurality of monocrystalline diamond seeds, wherein during the step of positioning the monocrystalline diamond seeds so as to form a mosaic, each monocrystalline diamond seed comprises angles giving the directions of propagation of the wave fronts ranging from −5° to +5° relative to the second value.

4. The production method according to claim 1, said method comprising a step of surfacing, by lithography or by laser, the crystallographic orientation faces (OC1, OC2) of the monocrystalline diamond seeds so that said seeds have angles giving the directions of propagation of the wave fronts which are substantially identical.

5. The production method according to claim 2, said method comprising a step of resurfacing by laser or by lithography of the monocrystalline diamond plate after removal of the monocrystalline diamond epitaxial layer, the resurfacing step comprising:
a removal of a predetermined thickness of the monocrystalline diamond plate,
a formation of a new predetermined terraced structure having crystallographic orientation faces (OC1, OC2) of monocrystalline diamond seeds comprising families of planes {100} or crystallographic orientation faces (OC1, OC2) of the monocrystalline diamond seeds comprising families of planes {100} and {113}.

6. The production method according to claim 5, wherein the seeds of the new terraced structure, formed during the resurfacing step by laser or by lithography, have angles giving the direction of propagation of the substantially identical wave fronts.

7. The production method according to claim 1, wherein the lateral epitaxial growth of the terraced structure according to the crystallographic orientation (OC2) of the monocrystalline diamond seeds, comprises a step of introducing a suitable gas to prevent the development of stresses or the formation of crystalline defects, at an interface between the seeds.

8. The production method according to claim 1, wherein the terraced structure comprises macroscopic growth steps.

9. The production method according to claim 1, said method further comprising a step of creating centers “XV-”, by doping with a suitable gas “X”, followed by electron beam irradiation and annealing.

10. The production method according to claim 1, wherein the monocrystalline diamond seeds are positioned in order of increasing thickness according to a direction of propagation defined by one of the angles of the wave fronts.

11. A monocrystalline diamond plate obtained by the production method according to claim 1, wherein at least 15% of junctions formed between the monocrystalline diamond seeds have a width value of Raman peak at half-height greater than or equal to 2.5 cm−1 and less than 2.9 cm−1.

12. A monocrystalline diamond obtained by the production method according to claim 1, having a surface comprising at least a first crystallographic face and a second crystallographic face, said crystallographic faces each being associated with a concentration of center “XV-”; the concentration of center “XV-” of the first crystallographic face being greater than the concentration of center “XV-” of the second crystallographic face.

13. The monocrystalline diamond according to claim 12, wherein the first crystallographic face of the monocrystalline diamond belongs to the family of planes {113}.

14. A method of manufacturing an optical window, a substrate for a semiconductor or for thermal management, a substrate for quantum technologies, or a diamond for jewelry greater than 5 carats, comprising processing the monocrystalline diamond plate according to claim 11.

15. The production method according to claim 1, wherein the difference between the first values describing the angles giving the directions of propagation of the wave fronts for the two adjacent monocrystalline diamond seeds is less than or equal to 1°.

16. The production method according to claim 3, wherein the angles giving the directions of propagation of the wave fronts for each of the monocrystalline diamond seeds range from −2.5° to +2.5°.

17. The production method according to claim 7, said gas being suitable to prevent the formation of twin defects and dislocation defects.

18. The monocrystalline diamond plate according to claim 11, wherein at least 50% of said junctions have a width value of Raman peak at half-height greater than or equal to 2.5 cm−1 and less than 2.9 cm−1.
